(19) United States
(12) Patent Application Publication
(10) Pub. No.: US 2002/0137306 A1
(43) Pub. Date: Sep. 26, 2002

(54) Method for forming polysilicon-filled trench isolations

(76) Inventor: Tai-Ju Chen, Tainan City (TW)

Correspondence Address: POWELL, GOLDSTEIN, FRAZER & MURPHY LLP, P.O. BOX 97223, WASHINGTON, DC, 20090-7223, US

(21) Appl. No.: 09/813,047

(22) Filed: Mar. 20, 2001

(51) Int. Cl. H01L 21/76

(52) U.S. Cl. 438/430; 438/432

(57) ABSTRACT

A method for forming polysilicon-filled trench isolations is provided. The present method is characterized in that using nitrogen implantation to amorphize the top portion of the polysilicon filled in the trench isolation and then a nitrogen-implanted region formed in this top portion. The nitrogen-implanted region forms an oxynitride cap layer during the polysilicon oxidation. The oxynitride cap layer provides better erosive resistance to acidic solutions for stripping away photopresist layers used for several wells/Vₜₕ implantations than a silicon dioxide layer. The oxynitride cap layer also reduces the gate-to-channel fringing field because its dielectric constant is higher than that of silicon dioxide. Moreover, the nitrogen-implanted region in the top portion of the polysilicon decreases the polysilicon oxidation time so that the channel edge oxidation is reduced.

### BACKGROUND OF THE INVENTION

1. Field of the Invention

The present invention relates to an isolation technology employed in the semiconductor process, and more particularly to a method for forming polysilicon-filled trench isolations.

2. Description of the Prior Art

Shallow trench isolation (STI) has replaced LOCOS as the dominant isolation technique for CMOS at the 0.25 μm technology node. To date STI has facilitated the continued scaling of device and isolation widths commensurate with the design rule. While the channel edge effect, such as the fringing gate-to-channel electric field, will strongly increase with reducing feature size. The fringing gate-to-channel electric field significantly lowers the threshold voltage at the edge of the channel on the 100-nm scale size. This results in increased off-state current and threshold voltage roll-off in narrow devices, which would increase the stand-by power consumption, both undesirable impacts on IC product design. A method for inserting a conductive field plate into the trench, such as a polysilicon field plate, is proposed to minimize the gate-to-channel fringing effect. FIG. 1 shows schematically the gate-to-channel fringing fields indicated by the dotted line 1 and the mechanism by which the polysilicon-filled trench 2 reduces the impact of these fields. In general, a silicon dioxide layer 3 is formed over the polysilicon-filled trench 2, whereby when an operational voltage is applied on the polysilicon gate 4, the generated electric field is partially directed to the space between the polysilicon gate 4 and the polysilicon-filled trench 2. Therefore, the gate-to-channel fringing field effect is reduced.

FIG. 2A to FIG. 2D shows various steps for forming a prior polysilicon-filled shallow trench isolation device. In FIG. 2A, a silicon substrate 100 with a pad oxide layer 101 formed thereon is firstly provided. Next, a silicon nitride layer 102 is formed on the pad oxide layer 101. Then, forming a plurality of shallow trench isolations in the silicon substrate 100 by way of anisotropically etching. Following, forming an oxide liner layer 103 on the surface of each of the shallow trench isolations. Thereafter, depositing a polysilicon layer 104 on the silicon nitride layer 102 to fill each of the shallow trench isolations. Planarizing the polysilicon layer 104 until the silicon nitride layer 102 by way of chemical mechanical polishing method. Then, referring to FIG. 2A, etching back the polysilicon 104 filled in the shallow trench isolation to further recess the polysilicon 104. Subsequently, in FIG. 2B, proceeding polysilicon oxidation process to form a silicon dioxide cap layer 105 on the top of the polysilicon 104 filled in the shallow trench isolation. Then, sequentially removing the silicon nitride layer 102 and the pad oxide layer 101 to form polysilicon-filled shallow trench isolation with a silicon dioxide cap layer 105, as shown in FIG. 2C.

Continuously, referring to FIG. 2C, forming a photoresist layer 106 on the silicon substrate 100 and then performing channel implantation to adjust the threshold voltage. Following, referring to FIG. 2D, forming a gate oxide layer 107 on the silicon substrate 100 and then, a polysilicon gate layer 108 on the gate oxide layer 107 and the silicon dioxide cap layer 105. Finally, performing ion implantation to form a source/drain (not shown) beside each side of the polysilicon gate 108 in the silicon substrate 100 between each pair of the shallow trench isolations.

However, there are some disadvantages existing in the prior method for forming polysilicon-filled shallow trench isolations, as follows:

1. The time for the polysilicon oxidation to form the silicon dioxide cap layer 105 is long, and thus the lateral oxidation of the channel 109 is easily happened to narrow the width of the channel 109.

2. The silicon dioxide cap layer 105 on the polysilicon-filled shallow trench isolation is easily etched away by acidic solutions for stripping away photoresist layers used for several wells/Vₜₕ implantations, and even exposing the polysilicon 104 filled in the shallow trench isolation. As a result, the polysilicon gate 108 will contact with the polysilicon 104 filled in the shallow trench isolation.

Accordingly, it is an intention to provide a method for forming polysilicon-filled shallow trench isolation with a protective cap layer formed thereon to overcome the drawbacks encountered in the prior method.

### SUMMARY OF THE INVENTION

It is an objective of the present invention to provide a method for forming polysilicon-filled trench isolations, in which using nitrogen implantation to amorphize the top portion of polysilicon filled in the trench isolation to form a nitrogen-implanted region. The nitrogen-implanted region reduces the polysilicon oxidation time for forming an oxynitride cap layer from the nitrogen-implanted region than a silicon dioxide cap layer, and thus reduces the channel edge narrowing effect during the polysilicon oxidation.

Another objective of the present invention is to provide a method for forming polysilicon-filled trench isolation with an oxynitride cap layer formed thereon. The oxynitride cap layer provides better erosive resistance to acidic solutions for stripping away photoresist layers used for several wells/Vₜₕ implantations than a silicon dioxide cap layer. And, the oxynitride cap layer reduces the gate-to-channel fringing field because its dielectric constant is higher than that of silicon dioxide.

In order to achieve the above objectives, the present invention provides a method for forming polysilicon-filled trench isolations. At first, a silicon substrate having a pad dielectric layer formed thereon is provided. Next, forming a polishing stopping layer over the pad dielectric layer. Anisotropically etching the polishing stopping layer, the pad dielectric layer and the silicon substrate to form a trench isolation in the silicon substrate. Subsequently, forming a liner layer over the surface of the trench isolation. Afterward, forming a polysilicon layer over the polishing stopping layer and the liner layer. Then, planarizing the polysilicon layer until exposing the polishing stopping layer. Following, etching back a partial portion of the polysilicon layer. Subsequently, performing ion implantation to form an ion-implanted layer on the polysilicon layer. Proceeding a first thermal oxidation so that the ion-implanted layer forms a cap oxide layer. Finally, sequentially removing said polishing stopping layer and said pad dielectric layer.

### BRIEF DESCRIPTION OF THE DRAWINGS

The present invention can be best understood through the following description and accompanying drawings, wherein:

FIG. 1 shows a schematic cross-sectional view of a MOSFET device perpendicular to the direction of current flow. The gate-to-channel fringing field is illustrated.

FIG. 2A to FIG. 2D shows schematic cross-sectional views of various steps for forming a prior polysilicon-filled shallow trench isolation device; and

FIG. 3A to FIG. 3H shows schematic cross-sectional views of various steps for forming polysilicon-filled trench isolation according to one embodiment of the present invention.

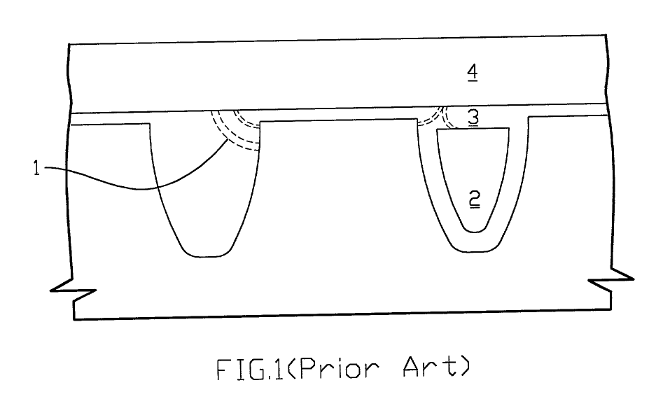

### DESCRIPTION OF THE PREFERRED EMBODIMENTS

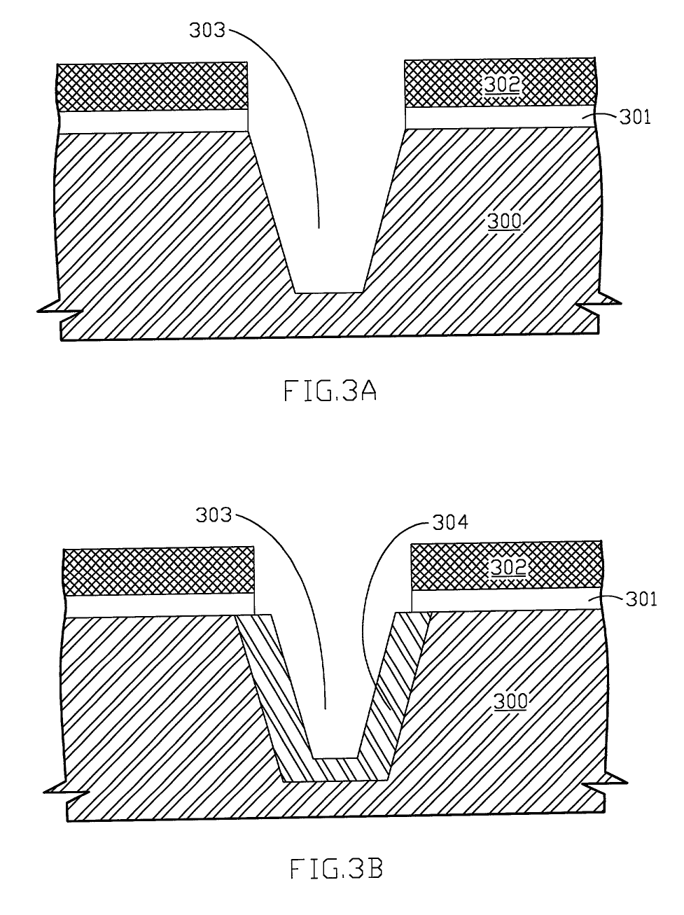

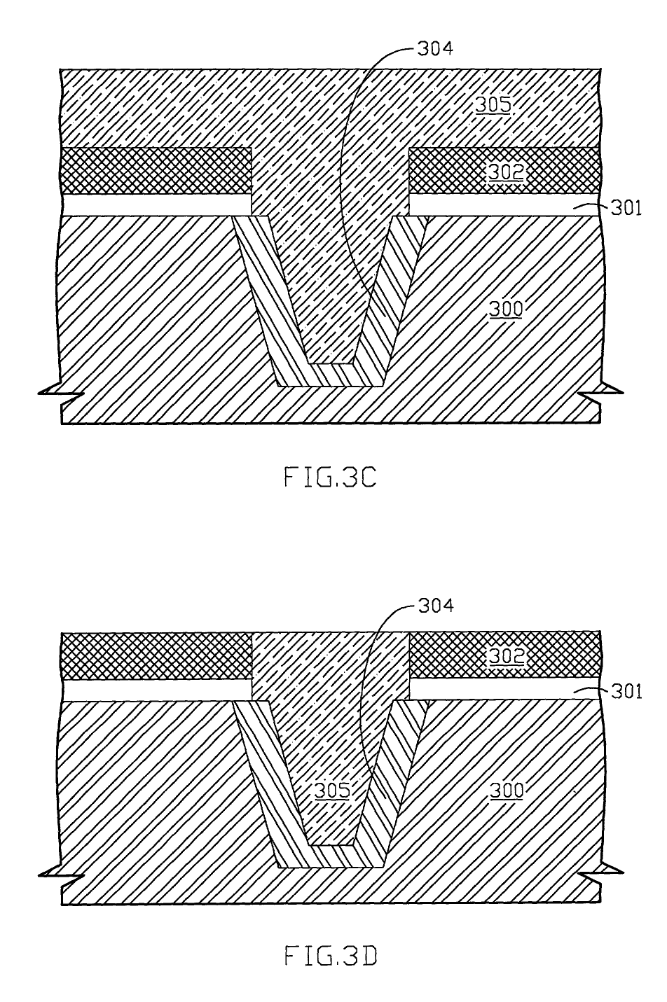

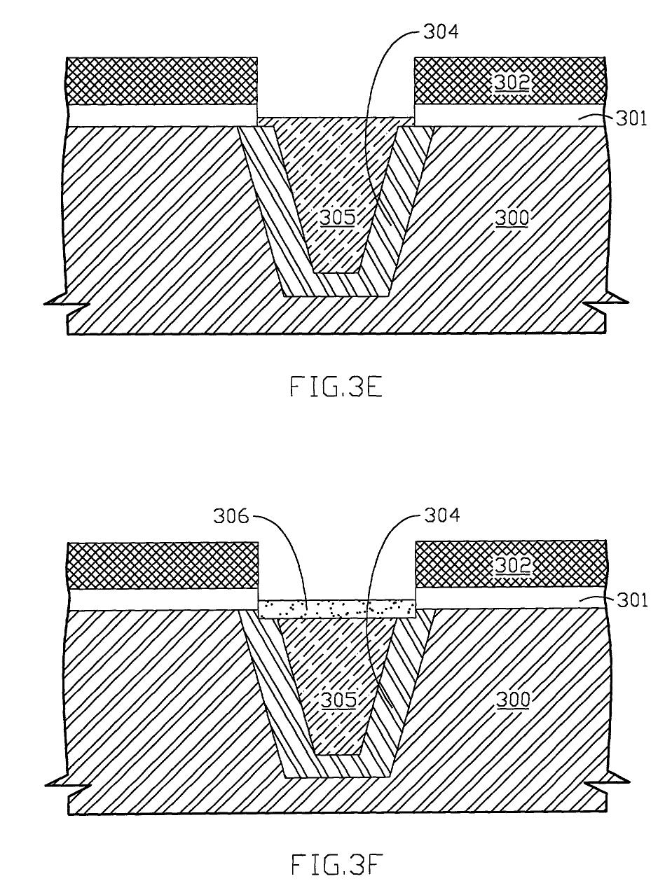

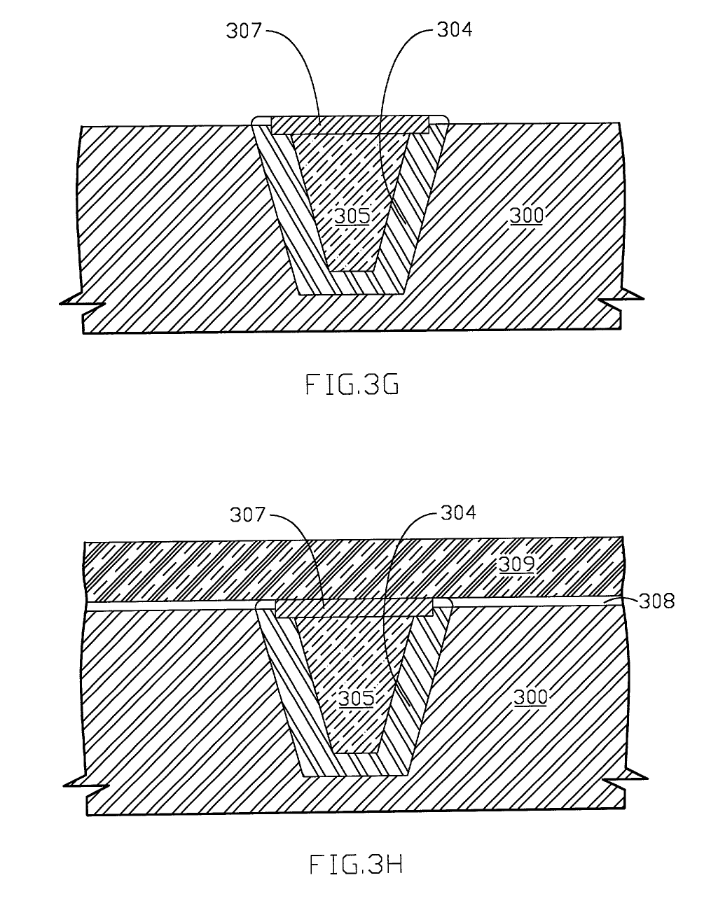

Referring to FIG. 3A, a silicon substrate 300 is firstly provided. Then, forming a pad dielectric layer 301 on the substrate 300. The pad dielectric layer 301 can be formed of a silicon dioxide layer by way of thermal oxidation. Next, a polishing stopping layer 302 is formed on the pad dielectric layer 301. The polishing stopping layer 302 can be formed of silicon nitride by way of low pressure chemical vapor deposition method (LPCVD) using the reaction gases of SiH₂Cl₂ and NH₃ at the temperature of about 700˜800° C. under the operational pressure of about 0.1˜1 torr. Alternately, the polishing stopping layer 302 of silicon nitride can be formed of plasma enhanced chemical vapor deposition method (PECVD) using the reaction gases of SiH₄, NH₃ and N₂ at the temperature of about 250˜400° C. under the operational pressure of about 1˜5 torr. Thereafter, anisotropically etching the polishing stopping layer of silicon nitride 302, the pad dielectric layer of silicon dioxide 301 and the silicon substrate 300 to form a plurality of trench isolations 303 in the silicon substrate 300.

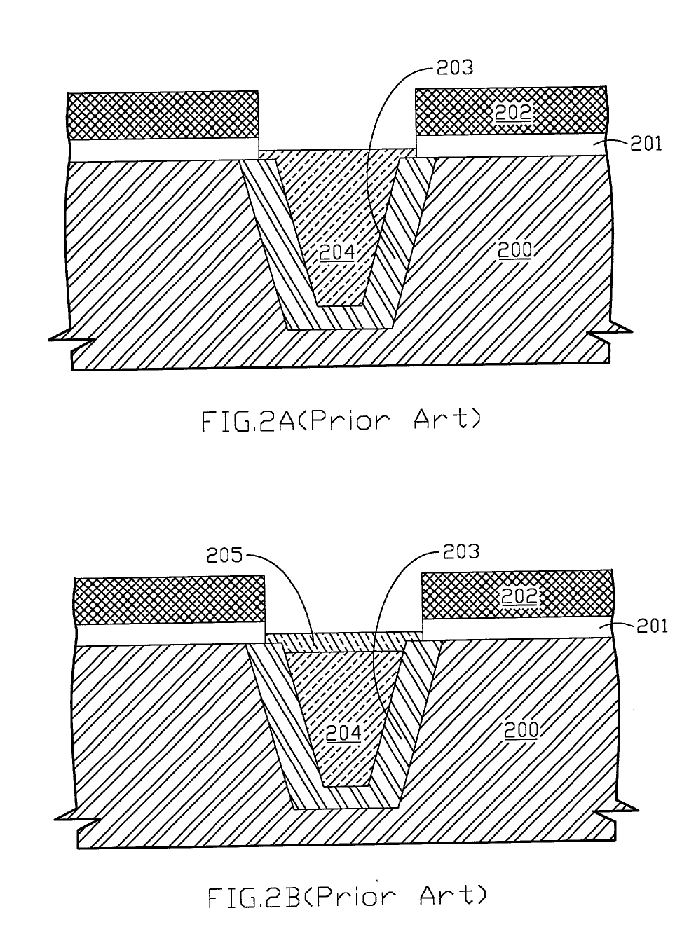

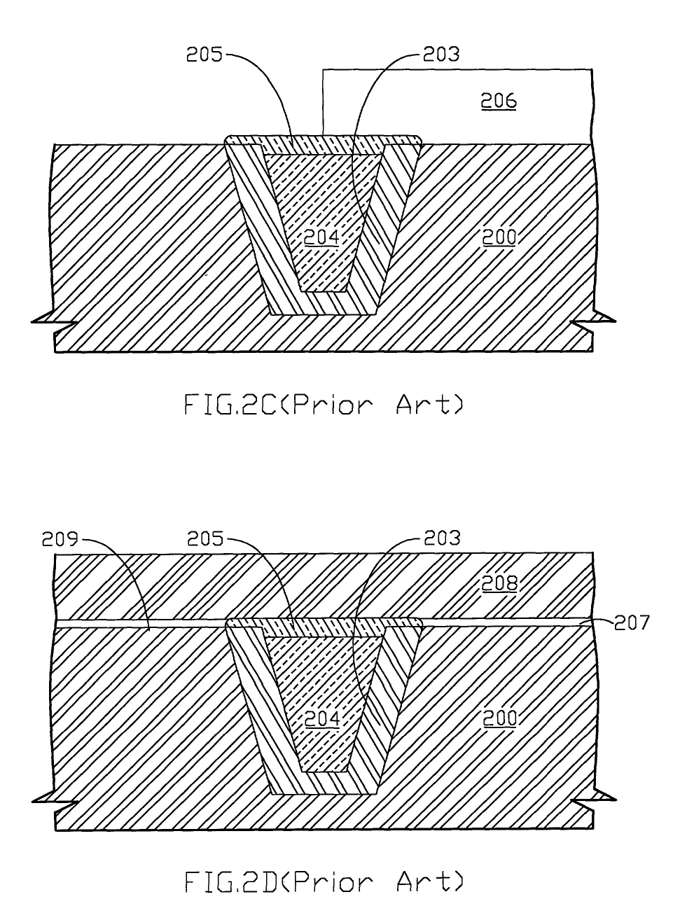

Referring to FIG. 3B, a liner layer 304 is formed on the surface of each of the trench isolations 303. The liner layer 304 can be formed of silicon dioxide by way of thermal oxidation. Then, referring to FIG. 2C, a polysilicon layer 305 is formed on the polishing stopping layer of silicon nitride 302 to fill each of the trench isolations 303. The polysilicon layer 305 can be formed of low pressure chemical vapor deposition method using SiH₄ (silane) as the reaction gas at the temperature of about 600˜650° C. under the operational pressure of about 0.3˜0.6 torr. The polysilicon layer 305 also can be formed of in-situ N⁺ polysilicon by way of low pressure chemical vapor deposition method using the reaction gases of SiH₄ and 1 Vol. % AsH₃.

Referring to FIG. 3D, planarizing the polysilicon layer 305 by way of chemical mechanic polishing method until the polishing stopping layer of silicon nitride 302. Then, referring to FIG. 3E, etching back the polysilicon layer 305 to further recess the polysilicon layer 305 while maintaining the level of the polysilicon layer 305 to exceed the surface of the silicon substrate 300. The process for etching back the polysilicon layer 305 can be performed by way of reactive ion etching method using the source gas selected from the group consisting of Cl₂, HCl and SiCl₄.

Referring to FIG. 3F, proceeding nitrogen implantation to amorphize the top portion of the polysilicon layer 305 to form a nitrogen-implanted region 306. The nitrogen implantation can be performed using the source gas, such as N₂ and NH₃, with the dosage of about 5×10¹⁴ to about 5×10¹⁶ ions/cm², at the implanting energy of about 10 KeV.

Referring to FIG. 3G, proceeding polysilicon oxidation by way of thermal oxidation, such as dry oxidation at the temperature of about 1000° C. to form an oxynitride cap layer 307 from the nitrogen-implanted region 306. Then, removing the polishing stopping layer of silicon nitride 302 by way of wet dip etching with aqueous H₃PO₄ solution. Following, removing the pad dielectric layer of silicon dioxide 301 by wet dip etching with aqueous HF solution. Thereby, polysilicon-filled trench isolation with an oxynitride cap layer 307 is provided.

Referring to FIG. 3H, forming a photoresist layer on the silicon substrate 300 to proceed channel implantation so as to adjust the threshold voltage Vₜₕ. Thereafter, the photoresist layer is stripped away with acidic solution. Subsequently, forming a gate oxide layer 308 on the silicon substrate 300, and then forming a polysilicon gate layer 309 on the gate oxide layer 308 and the oxynitride cap layer 307. Finally, using ion implantation to form a source/drain beside each side of the polysilicon gate layer 309 in the silicon substrate 300. Thereby, a plurality of polysilicon-filled STI devices are obtained.

In view of the foregoing, the top portion of the polysilicon layer 305 is amorphized to form a nitrogen-implanted region 306. Therefore, the polysilicon oxidation time to oxidize the nitrogen-implanted region 306 is reduced, and thus the lateral oxidation of the channel edge is also reduced to prevent the channel width from narrowing. The oxynitride cap layer 307 provides better erosive resistance to the acidic solution used for stripping away the photoresist layer than that of silicon dioxide. Thus, the oxynitride cap layer 307 acts as a protection layer of the polysilicon layer 305 filled in the trench isolation to prevent it from being exposed. Besides, the oxynitride cap layer 307 also reduces the gate-to-channel fringing field because its dielectric constant is higher than that of silicon dioxide.

In the preferred embodiments of the present invention, using nitrogen implantation to amorphize the top portion of the polysilicon layer 305, so as to reduce its oxidation time. However, any kind of ion source which can amorphize the top portion of the polysilicon layer 305, and the subsequent oxidized cap layer provides a higher dielectric constant than silicon dioxide to reduce the gate-to-channel fringing effect, is suitable for the present ion implantation except for nitrogen implantation.

The preferred embodiments are only used to illustrate the present invention, not intended to limit the scope thereof. Many modifications of the preferred embodiments can be made without departing from the spirit of the present invention.

What is claimed is:

1. A method for forming polysilicon-filled trench isolation, comprising:
providing a silicon substrate having a pad dielectric layer formed thereon;
forming a polishing stopping layer over said pad dielectric layer;
anisotropically etching said polishing stopping layer, said pad dielectric layer and said silicon substrate to form a trench isolation in said silicon substrate;
forming a liner layer over the surface of said trench isolation;
forming a polysilicon layer over said polishing stopping layer and said liner layer;
planarizing said polysilicon layer until exposing said polishing stopping layer;
etching back a partial portion of said polysilicon layer;
performing ion implantation to form an ion-implanted layer on said polysilicon layer;
proceeding a first thermal oxidation so that said ion-implanted layer forms a cap oxide layer; and
sequentially removing said polishing stopping layer and said pad dielectric layer.

2. The method of claim 1, wherein said pad dielectric layer comprises silicon dioxide.

3. The method of claim 2, wherein said pad dielectric layer of silicon dioxide is formed by way of a second thermal oxidation.

4. The method of claim 1, wherein said polishing stopping layer comprises silicon nitride.

5. The method of claim 4, wherein said polishing stopping layer of silicon nitride is formed by way of low pressure chemical vapor deposition method utilizing SiH₂Cl₂ and NH₃ as the reaction gases at the temperature of about 700˜800° C. under the operation pressure of about 0.1˜1 torr.

6. The method of claim 4, wherein said polishing stopping layer of silicon nitride is formed by way of plasma enhanced chemical vapor deposition method utilizing SiH₄, NH₃ and N₂ as the reaction gases at the temperature of about 250˜400° C. under the operation pressure of about 1˜5 torr.

7. The method of claim 1, wherein said liner layer comprises silicon dioxide.

8. The method of claim 7, wherein said liner layer of silicon dioxide is formed by way of a third thermal oxidation.

9. The method of claim 1, wherein said polysilicon layer is formed by way of low pressure chemical vapor deposition method utilizing SiH₄ as the reaction gas at the temperature of about 600˜650° C. under the operation pressure of about 0.3˜0.6 torr.

10. The method of claim 1, wherein said polysilicon layer is formed of in-situ N⁺ polysilicon layer by way of low pressure chemical vapor deposition method utilizing SiH₄ and 1 Vol. % AsH₃ as the reaction gases.

11. The method of claim 1, wherein said polysilicon layer is planarized by way of chemical mechanical polishing method.

12. The method of claim 1, wherein said polysilicon layer is etched back by way of reactive ion etching method utilizing an etching gas selected from a group consisting of Cl₂, HCl and SiCl₄.

13. The method of claim 1, wherein said ion implantation is performed by way of nitrogen implantation.

14. The method of claim 13, wherein said nitrogen implantation is performed utilizing the gas source of N₂ with a dosage of about 5×10¹⁴˜5×10¹⁶ ions/cm² under an implanting energy of about 10 KeV.

15. The method of claim 13, wherein said nitrogen implantation is performed utilizing the gas source of NH₃ with a dosage of about 5×10¹⁴˜5×10¹⁶ ions/cm² under an implanting energy of about 10 KeV.

16. The method of claim 1, wherein said first thermal oxidation is proceeded by way of dry oxidation at the temperature of about 1000° C.

17. The method of claim 2, wherein said pad dielectric layer of silicon dioxide is removed by way of dip wet etch with aqueous HF solution.

18. The method of claim 4, wherein said polishing stopping layer of silicon nitride is removed by way of dip wet etch with aqueous H₃PO₄ solution.

19. A method for forming a polysilicon-filled trench isolation device, comprising:
providing a silicon substrate having a first silicon dioxide layer formed thereon;
forming a silicon nitride layer on said first silicon dioxide layer as a polishing stopping layer;
anisotropically etching said silicon nitride layer, said first silicon dioxide layer and said silicon substrate to form a trench isolation in said silicon substrate;
forming a second silicon dioxide liner layer over the surface of said trench isolation;
forming a polysilicon layer over said silicon nitride layer and said second silicon dioxide liner layer;
planarizing said polysilicon layer until exposing said silicon nitride layer;
etching back a partial portion of said polysilicon layer;
performing a first ion implantation to form a nitrogen-implanted layer on said polysilicon layer;
proceeding a first thermal oxidation so that said nitrogen-implanted layer forms an oxynitride cap layer;
sequentially removing said silicon nitride layer and said first silicon dioxide layer;
forming a photoresist layer over said silicon substrate and performing channel implantation;
sequentially forming a gate oxide layer and a polysilicon gate layer on said silicon substrate; and
proceeding a second ion implantation to form a source/drain beside each side of said polysilicon gate layer in said silicon substrate.

20. The method of claim 19, wherein said second silicon dioxide liner layer is formed by way of a second thermal oxidation.

21. The method of claim 19, wherein said polysilicon layer is formed by way of low pressure chemical vapor deposition method utilizing SiH₄ as the reaction gas at the temperature of about 600˜650° C. under the operation pressure of about 0.3˜0.6 torr.

22. The method of claim 19, wherein said polysilicon layer is formed of in-situ N⁺ polysilicon layer by way of low pressure chemical vapor deposition method utilizing SiH₄ and 1 Vol. % AsH₃ as the reaction gases.

23. The method of claim 19, wherein said polysilicon layer is planarized by way of chemical mechanical polishing method.

24. The method of claim 19, wherein said polysilicon layer over said trench isolation is etched back by way of reactive ion etching method utilizing an etching gas selected from a group consisting of Cl₂, HCl and SiCl₄.

25. The method of claim 19, wherein said first ion implantation is performed by way of nitrogen implantation.

26. The method of claim 25, wherein said nitrogen implantation is performed utilizing the gas source of N₂ with a dosage of about 5×10¹⁴˜5×10¹⁶ ions/cm² under an implanting energy of about 10 KeV.

27. The method of claim 25, wherein said nitrogen implantation is performed utilizing the gas source of NH₃ with a dosage of about 5×10¹⁴˜5×10¹⁶ ions/cm² under an implanting energy of about 10 KeV.

28. The method of claim 19, wherein said first thermal oxidation is proceeded by way of dry oxidation at the temperature of about 1000° C.

29. The method of claim 19, wherein said first silicon dioxide layer is removed by way of dip wet etch with aqueous HF solution.

30. The method of claim 19, wherein said silicon nitride layer is removed by way of dip wet etch with aqueous H₃PO₄ solution.
